(19) United States
(12) Patent Application Publication
(10) Pub. No.: US 2022/0122660 A1
(43) Pub. Date: Apr. 21, 2022

(54) CONFIGURATION AND METHOD OF OPERATION OF A ONE-TRANSISTOR TWO-RESISTORS (1T2R) RESISTIVE MEMORY (RERAM) CELL AND AN ARRAY THEREOF

(71) Applicant: Weebit Nano Ltd., Hod Hasharon (IL)

(72) Inventor: Yoav NISSAN-COHEN, Mishmar David (IL)

(73) Assignee: Weebit Nano Ltd., Hod Hasharon (IL)

(21) Appl. No.: 17/565,777

(22) Filed: Dec. 30, 2021

Related U.S. Application Data
(63) Continuation of application No. PCT/US2020/042873, filed on Jul. 21, 2020.
(60) Provisional application No. 62/876,985, filed on Jul. 22, 2019.

(51) Int. Cl. G11C 13/00

(52) U.S. Cl. CPC G11C 13/004; G11C 13/0069; H01L 27/2436; G11C 2013/0042; G11C 2213/79; G11C 13/003

(57) ABSTRACT

A semiconductor resistive random-access memory (ReRAM) device of an array including at least one ReRAM cell is provided. The ReRAM cell includes a word line; a select line; a first bit line; a second bit line having a polarity opposite of that of the first bit line; a first resistor having a first terminal and a second terminal, wherein the second terminal of the first resistor is connected to the first bit line; a second resistor having a first terminal and a second terminal, the second terminal of the second resistor is connected to the second bit line; and a transistor having a gate terminal, a source terminal and a drain terminal; the word line is connected to the gate terminal, the select line connected to the source terminal, and the drain terminal connected to the first terminal of the first resistor and the first terminal of the second resistor.

### CROSS-REFERENCE TO RELATED APPLICATIONS

This application is a continuation of PCT Application No.: PCT/US2020/042873, filed Jul. 21, 2020, now pending, which claims the benefit of U.S. Provisional Application No. 62/876,985 filed on Jul. 22, 2019. The contents of the above-referenced applications are hereby incorporated by reference.

### TECHNICAL FIELD

The present disclosure generally relates to resistive random-access memory (ReRAM) cells, and more particularly to write to and read from one-transistor two-resistor (1T2R) class of ReRAM cells.

### BACKGROUND

In the art there are many types of known non-volatile random-access memory (RAM) cells. These kinds of memory cells allow the random access to each memory cell, or group of cells if so configured, and ensure that these data is retained in the memory cell even when power is lost. A certain class of these memory cells is the resistive RAM (ReRAM) cells. In these cells data is stored by changing the resistance of a dielectric solid-state material. The process of operation of the ReRAM cell includes the forming of the cell. This typically requires creating a filament which thereafter may be reset, or broken, for the purpose of creating a high resistance, or set, in fact reformed so that low resistance is achieved.

In the related art, a variety of ReRAM cells may be found, typically of having a resistors only cross-point configuration, a configuration having a single transistor and a single resistor (1T1R), a configuration having a single transistor and two resistors (1T2R), and a configuration having two transistors and two resistors (2T2R).

The first and most basic is the cross-point configuration, where there are no transistors. Only a resistor is used to connect a word and a bit line. The leak paths which are formed in this configuration affect the accuracy of read operations of the single resistor (1R) ReRAM cell in the cross-point configuration array and is a major problem particularly at high temperatures. In the 1T1R configuration, a transistor is added to overcome the leak path problem, since all unselected word lines are isolated from the corresponding bit line and the leak paths are presented with a very high resistance path. This configuration, however, is costly in terms of area since most of the cell area is now occupied by a transistor.

To overcome the significant area penalty of 1T1R, an 1TnR configuration is employed, where ‘n’ is an integer greater than ‘1’. The leakage is still lower than in the cross-point configuration, but is not completely eliminated as in the 1T1R case. This is because of existing leak paths through the other (n-1) resistors which are connected to the same transistor. A compromise between the cross-point and the 1T1R, the 1TnR achieves leak paths lower than cross-point, at an area penalty that is not as high as in the 1T1R case.

In both 1T1R and 1T2R the endurance is limited and the read window is known to be problematic. This is resolved with the 2T2R configuration, at an area penalty that is even higher than 1T2R. However, the differential reading gives a better operating window and reliability. In an array configuration using 1T1R ReRAM cells, each resistor is connected on one side to a bit line (BL), and on the other side to a select line (SL) controlled by a select transistor that is switched by a word line (WL). In practice, this configuration suffers from a small window separating “1” from “0” stored in the ReRAM cell. Therefore, aggressive programming (or writing) is required which in turn limits the endurance of the 1T1R ReRAM cell. The operation of programming and writing includes updating the content of a memory cell.

To overcome the limits of the 1T1R cell there appeared the 2T2R class of ReRAM cells. This class enables differential read that in turn increases the window separating the ‘1’ and ‘0’ states. As a result, lesser aggressive programming is required resulting in better endurance that may be achieved. However, this does not come without a price as the tradeoff in this case is an increase in the overall memory area due to the additional transistor that has the dominant impact of the area size of the 2T2R ReRAM cell.

While the 1T2R ReRAM cell has its area advantage over the 1T1R ReRAM cell, it does not have the endurance and reliability advantages of the 2T2R ReRAM cell. It is still necessary, as demonstrated in the related art, to overcome more efficiently its reliability drawbacks. Such solutions should provide higher endurance and a better programming window.

It would be therefore advantageous to provide a solution that would overcome the challenges noted above and achieve the reliability advantages without paying the penalty area.

### SUMMARY

A summary of several example embodiments of the disclosure follows. This summary is provided for the convenience of the reader to provide a basic understanding of such embodiments and does not wholly define the breadth of the disclosure. This summary is not an extensive overview of all contemplated embodiments and is intended to neither identify key or critical elements of all embodiments nor to delineate the scope of any or all aspects. Its sole purpose is to present some concepts of one or more embodiments in a simplified form as a prelude to the more detailed description that is presented later. For convenience, the term “some embodiments” or “certain embodiments” may be used herein to refer to a single embodiment or multiple embodiments of the disclosure.

Some embodiments disclosed herein include a semiconductor resistive random-access memory (ReRAM) device, comprising: an array including at least one ReRAM cell, wherein the ReRAM includes: a word line; a select line; a first bit line; a second bit line having a polarity opposite of that of the first bit line; a first resistor having a first terminal and a second terminal, wherein the second terminal of the first resistor is connected to the first bit line; a second resistor having a first terminal and a second terminal, wherein the second terminal of the second resistor is connected to the second bit line; and a transistor having a gate terminal, a source terminal and a drain terminal; wherein the word line is connected to the gate terminal, the select line connected to the source terminal, and the drain terminal connected to the first terminal of the first resistor and the first terminal of the second resistor.

In an embodiment the ReRAM device further comprises a control unit configured to write a first logical value into the at least one ReRAM cell, wherein the first resistor is reset to a high resistive value before the second resistor is set to a low resistive value.

Some embodiments disclosed herein include a semiconductor resistive random-access memory (ReRAM) device. The ReRAM device comprises an array comprising at least one ReRAM cell, wherein the ReRAM cell includes: a word line; a select line; a first bit line; a second bit line having a polarity opposite of that of the first bit line; a first resistor having a first terminal and a second terminal, wherein the second terminal of the first resistor is connected to the first bit line; a second resistor having a first terminal and a second terminal, wherein the second terminal of the second resistor is connected to the second bit line; and a transistor having a gate terminal, a source terminal and a drain terminal; wherein the word line is connected to the gate terminal, the select line connected to the source terminal, and the drain terminal connected to the first terminal of the first resistor and the first terminal of the second resistor, wherein the each of the at least one ReRAM cell is configured to operate in one state.

Some embodiments disclosed herein include a method for writing to a cell of semiconductor resistive random-access memory (ReRAM) device. The method comprises receiving a logical value to be written into the cell, the cell is a one-transistor two-resistor (1T2R) ReRAM having a first resistor and a second resistor; determining based on the received logical value which of the first resistor and the second resistor is to be reset to a high resistive value; resetting the resistor of the determined to be reset to a high resistive value; and setting the other resistor of the cell determined to a low resistive value, wherein the combined opposite values of the first resistor and the second resistor are indicative of the logical value.

Some embodiments disclosed herein include a method a cell of semiconductor resistive random-access memory (ReRAM) device. The method comprises determining a first resistive value of a first resistor of the cell, wherein the cell is a one-transistor two-resistor (1T2R) ReRAM cell; determining a second resistive value of a second resistor of the cell; assigning a first logical value on an output corresponding with the cell, when the first resistive value is high and the second resistive value is low; and assigning a second logical value on the output corresponding with the cell, when the first resistive value is low and the second resistive value is high.

### BRIEF DESCRIPTION OF THE DRAWINGS

The subject matter disclosed herein is particularly pointed out and distinctly claimed in the claims at the conclusion of the specification. The foregoing and other objects, features, and advantages of the disclosed embodiments will be apparent from the following detailed description taken in conjunction with the accompanying drawings.

FIG. 1 is a schematic diagram of a memory array comprising one-transistor two-resistor (1T2R) resistive random-access memory (ReRAM) cells according to an embodiment.

FIG. 2 is a schematic diagram of a ReRAM according to an embodiment.

FIG. 3 is a flowchart for programming a 1T2R ReRAM array according to an embodiment.

FIG. 4 is a table of the values provided on operation state of the 1T2R ReRAM array according to an embodiment.

FIG. 5 is a method for reading from a 1T2R ReRAM cell from the ReRAM, according to one embodiment.

### DETAILED DESCRIPTION

It is important to note that the embodiments disclosed herein are only examples of the many advantageous uses of the innovative teachings herein. In general, statements made in the specification of the present application do not necessarily limit any of the various claims. Moreover, some statements may apply to some inventive features but not to others. In general, unless otherwise indicated, singular elements may be in plural and vice versa with no loss of generality.

According to some example embodiments, a one-transistor two-resistor (1T2R) resistive random-access memory (ReRAM) is provided. The 1T2R ReRAM includes a single transistor and two resistors, the resistors made of a dielectric that can be set or reset. The writing of the cell into the 1T2R ReRAM is performed such that a first resistor of the cell and the second resistor of the cell are programmed in the opposite. That is, a first resistor is written to logical ‘0’ and the second resistor to logical ‘1’. When both are read, they represent a single bit of information. The read operation may be performed in parallel or serially. Only one of the resistors conducts and therefore the single transistor is sufficient to drive or limit the current in the low resistance state (LRS). At write, reset is performed first to avoid a low resistance path between the two resistors. The memory cell has an inherently higher endurance as well as a larger window that overcomes reading errors.

FIG. 1 shows a schematic diagram of a memory array 100 according to an embodiment. The array 100 includes 1T2R ReRAM cells 110, where each 1T2R resistive random-access memory (ReRAM) cell 110 include one transistor T1 and two resistors R0 and R1. The transistor may be, for example, a metal-oxide semiconductor (MOS).

The ReRAM array 100 may include ‘k’ rows of cells 110, ‘k’ being an integer of ‘1’ or greater, and ‘j’ columns, T being an integer of ‘1’ or greater. In a ReRAM cell 110, for example, ReRAM cell 110-k-j, the transistor Ti has its gate connected to a word line (WL) 120-k. The WL connects through the gates of all Ti transistors of each of the ReRAM cells of row ‘k’. The source of each T₁ of row ‘k’ is connected to a select line (SL) 130-k. The drain of T1 of ReRAM cell 110-k is connected to a first terminal of R0 and a first terminal of R1. The second terminal of R0 is connected to a first bit line (BL) 140-j while the second terminal of R1 is connected to a second bit line having the opposite polarity to that of the first bit line, also referred to as bit line bar (BLb) 150-1.

Each column of ReRAM arrays has its respective BL and BLb lines which allow for both writing and reading to and from a ReRAM cell. Such reading and writing is performed according to the principles described herein. The structure allows the use of differential read with this type of 1T2R cells as further explained herein. Such is made possible according to the write principles described herein where only one of R0 and R1 conducts and therefore a single transistor, T1 is needed to drive or limit the LRS current of the ReRAM cell 110.

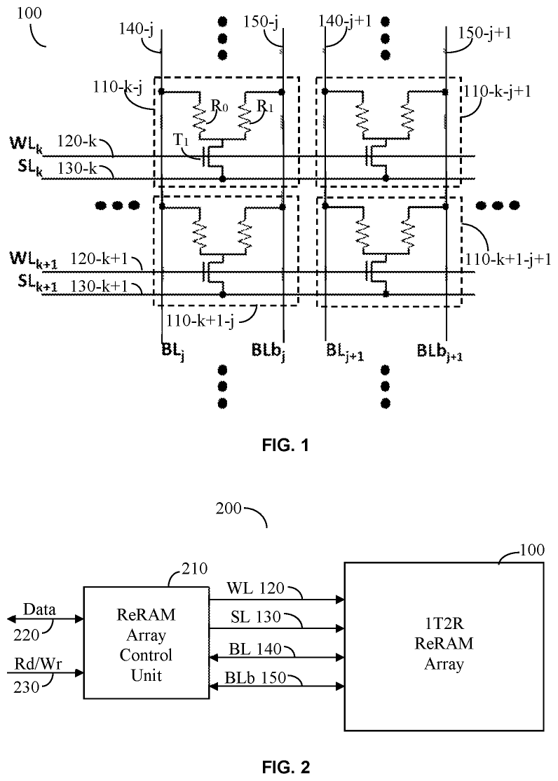

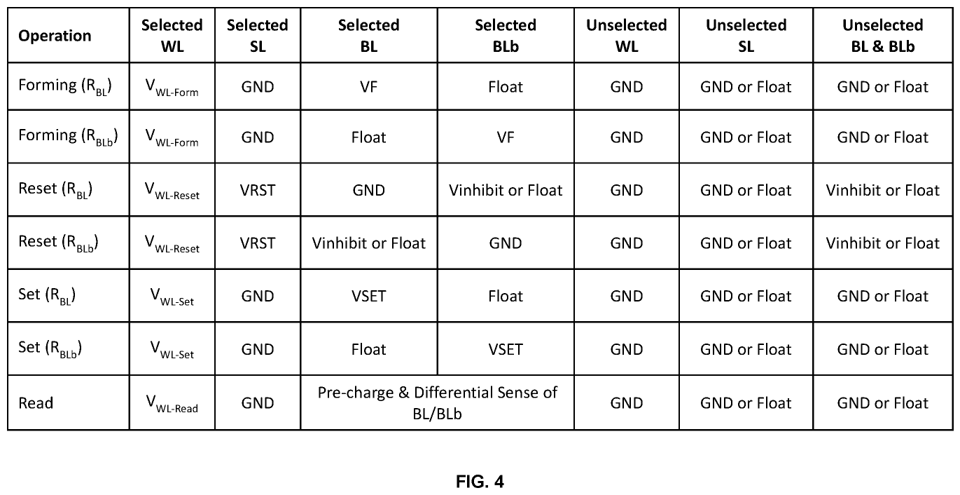

FIG. 2 depicts an example schematic diagram of a ReRAM 200 according to an embodiment. The ReRAM 200 includes a 1T2R ReRAM array, for example, the array 100 discussed herein with respect of FIG. 1. A ReRAM Array Control Unit (hereinafter control unit (CU)) 210 is configured to control the read and write operations of the ReRAM array 100. Four mode of operations may be performed by the control unit: forming, reset, set, and read. The particulars of each operation mode of each of these stages is summarized in the table provided in FIG. 4. The table includes example values provided on each of the selected and unselected WLs 120, SLs 130, BLs 140, and BLbs 150 of a 1T2R ReRAM array according to an embodiment.

Data to be written into the ReRAM array 100 or read therefrom is provided over an input/output 220. A read/write control signal 230 provides for an operation that the ReRAM 200 is expected to perform. In an embodiment, the writing sequence may enable the control unit 210 to ensure that the reset value is programmed first, to ensure that there is a high resistance of the path between the second terminal of R0 and the second terminal of R1. It should be noted that while the term “programming” is used herein, the term “writing” may and is frequently used to describe the same operation, i.e., updating the content of a memory cell. This is performed to avoid a situation where a low resistance path is created between a BL 140 and its corresponding BLb 150. It should be noted that, forming is the process where a filament is created from each dielectric to form the respective resistors R0 and R1.

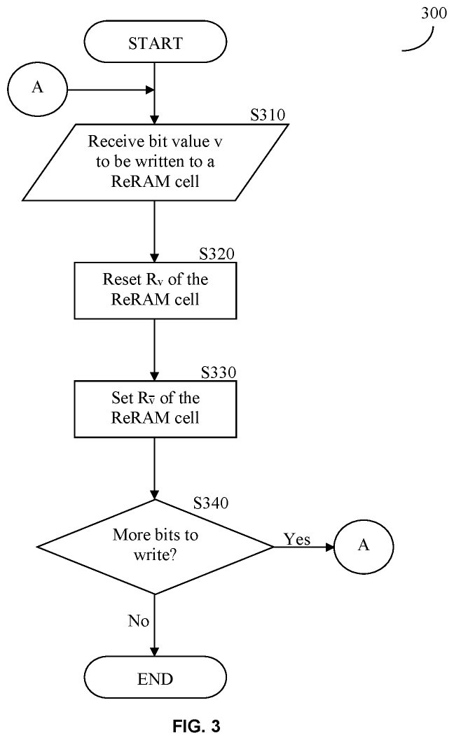

FIG. 3 shows an example flowchart 300 for programming a 1T2R ReRAM array according to an embodiment. At S310, a bit value ‘v’ is received to be written into a ReRAM cell, for example ReRAM cell 110-k-j. The value of v may be either ‘0’ or ‘1’. As noted, in an embodiment, it is necessary to ensure that, at no time, a path of low resistance is created between a BL 140 and its corresponding BLb 150, and therefore the order of programming is imperative. That is, it is essential to first reset one of the resistors of the ReRAM cell, for example cell 110-k-j, to a high resistance value before the other resistor of the cell is set to a low resistance value.

At S320, it is determined which of the resistors R0 and R1 should be reset. Hence, the write into the cell, according to the disclosed embodiment is performed in two steps. At S330, the resistor determined to have to be reset, is being set. For example, having R0 reset and R1 set may be the indication for the cell having a logical value of ‘1’, while having R0 set and R1 reset may be the indication for the cell having a logical value of ‘0’.

At S340, it is checked if additional bits should be written, and if so, execution returns to S310; otherwise, execution ends.

It should be appreciated that the opposite determination is equally plausible and therefore it is just a matter of an arbitrary decision of what combination constitutes a programming of a logical ‘1’ into the ReRAM cell 110-k-j and what constitutes a programming of a logical ‘0’ into the ReRAM cell 110-k-j.

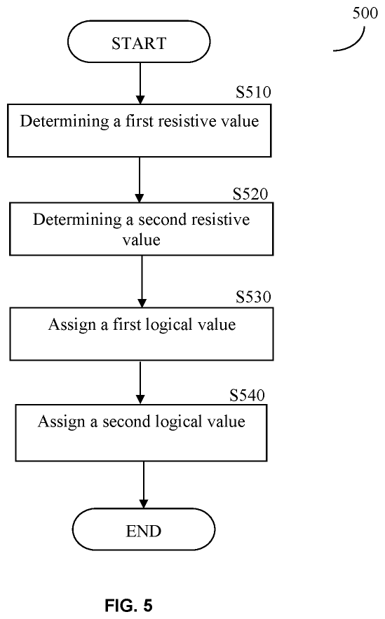

FIG. 5 shows an example flowchart 500 of a method for reading from a 1T2R ReRAM cell from the ReRAM, according to one embodiment.

At S510, a first resistive value of the first resistor of the 1T2R ReRAM cell is determined. Then, at S520, a second resistive value of a second resistor of the 1T2R ReRAM cell is determined. The first and second resistive values can be read in parallel or in serial.

At S530, a first logical value is assigned on an output corresponding with the 1T2R ReRAM cell when the first resistive value is high, and the second resistive value is low. The low and high values may be logical values (e.g., ‘0’ and ‘1’, respectively). Alternatively, at S540, a second logical value is assigned on the output corresponding with the 1T2R ReRAM cell if the first resistive value is low and the second resistive value is high. The first logical value is an opposite logical value of the second logical value. The 1T2R ReRAM cell is written such that at no time the first resistor and the second resistor have each a low resistive value.

In an embodiment, assigning value includes assigning a not a number (NaN) indication on the output corresponding with the 1T2R ReRAM cell if the first resistive value is high and the second resistive value is high.

Thus, according to one embodiment a read operation from the two cells can be done in a parallel fashion or in a serial fashion. In a parallel fashion the reading is performed as a differential reading in one step, while the differential reading in a serial manner is performed by first reading from the first resistor, for example R0 and then reading from the second resistor R1, or vice versa, and as long as opposite results were determined then the reading is valid. It should be appreciated that the suggested configuration increases the effective endurance of the ReRAM cell written to and read from in the manner described herein. Moreover, it should be noted that in the case where a high resistance value is determined to be the case for both resistors of the ReRAM cell 110, such case would be an indication that the ReRAM cell does not contain a valid numerical number and could be considered as not a number (NaN). It should be further noted that writing into the ReRAM array is possible after forming of the resistors of the ReRAM array in methods well-known in the art.

All examples and conditional language recited herein are intended for pedagogical purposes to aid the reader in understanding the principles of the disclosed embodiment and the concepts contributed by the inventor to furthering the art, and are to be construed as being without limitation to such specifically recited examples and conditions. Moreover, all statements herein reciting principles, aspects, and embodiments of the disclosed embodiments, as well as specific examples thereof, are intended to encompass both structural and functional equivalents thereof. Additionally, it is intended that such equivalents include both currently known equivalents as well as equivalents developed in the future, i.e., any elements developed that perform the same function, regardless of structure.

It should be understood that any reference to an element herein using a designation such as “first,” “second,” and so forth does not generally limit the quantity or order of those elements. Rather, these designations are generally used herein as a convenient method of distinguishing between two or more elements or instances of an element. Thus, a reference to first and second elements does not mean that only two elements may be employed there or that the first element must precede the second element in some manner. Also, unless stated otherwise, a set of elements comprises one or more elements.

As used herein, the phrase “at least one of” followed by a listing of items means that any of the listed items can be utilized individually, or any combination of two or more of the listed items can be utilized. For example, if a system is described as including “at least one of A, B, and C,” the system can include A alone; B alone; C alone; 2A; 2B; 2C; 3A; A and B in combination; B and C in combination; A and C in combination; A, B, and C in combination; 2A and C in combination; A, 3B, and 2C in combination; and the like.

What is claimed is:

1. A semiconductor resistive random-access memory (ReRAM) device, comprising:
an array including at least one ReRAM cell, wherein the ReRAM cell includes:
a word line;
a select line;
a first bit line;
a second bit line having a polarity opposite of that of the first bit line;
a first resistor having a first terminal and a second terminal, wherein the second terminal of the first resistor is connected to the first bit line;
a second resistor having a first terminal and a second terminal, wherein the second terminal of the second resistor is connected to the second bit line; and
a transistor having a gate terminal, a source terminal, and a drain terminal;
wherein the word line is connected to the gate terminal, the select line connected to the source terminal, and the drain terminal connected to the first terminal of the first resistor and the first terminal of the second resistor.

2. The ReRAM device of claim 1, further comprising:
a control unit configured to write a first logical value into the at least one ReRAM cell, wherein the first resistor is reset to a high resistive value before the second resistor is set to a low resistive value.

3. The ReRAM device of claim 2, wherein the control unit is further configured to:
write a second logical value into the at least one ReRAM cell such that the second resistor is reset to a high resistive value before the first resistor is set to a low resistive value, wherein the first logical value and the second logical value have opposite logical value.

4. The ReRAM device of claim 3, wherein the control unit is further configured to:
determine the resistive value of the first resistor;
determine the resistive value of the second resistor;
determine the logical value stored in the at least one ReRAM cell; and
perform a read operation of the at least one ReRAM cell.

5. The ReRAM device of claim 2, wherein the control unit is further configured to:
determine, in parallel, the resistive value of each of the first resistor and the second resistor of the at least one ReRAM cell;
determine a logical value stored in the at least one ReRAM cell; and
perform a read operation of the at least one ReRAM cell.

6. The ReRAM device of claim 2, wherein the control unit is further configured to:
provide a not a number (NaN) indication upon determination that both the first resistor and the second resistor have the high resistance value.

7. A semiconductor resistive random-access memory (ReRAM) device, comprising:
an array comprising at least one ReRAM cell, wherein the ReRAM cell includes:
a word line;
a select line;
a first bit line;
a second bit line having a polarity opposite of that of the first bit line;
a first resistor having a first terminal and a second terminal, wherein the second terminal of the first resistor is connected to the first bit line;
a second resistor having a first terminal and a second terminal, wherein the second terminal of the second resistor is connected to the second bit line;
and a transistor having a gate terminal, a source terminal and a drain terminal;
wherein the word line is connected to the gate terminal, the select line connected to the source terminal, and the drain terminal connected to the first terminal of the first resistor and the first terminal of the second resistor, wherein the each of the at least one ReRAM cell is configured to operate in one state.

8. The ReRAM device of claim 7, wherein the operation state of the ReRAM cell includes any one of: the first resistor is at a high resistance and the second resistor is at a high resistance; the first resistor is at a high resistance and the second resistor is at a low resistance; and the first resistor is at a low resistance and the second resistor is at a high resistance.

9. The ReRAM device of claim 8, wherein the first resistor at the high resistance and the second resistor at the high resistance indicates a not a number (NaN) state.

10. The ReRAM device of claim 8, wherein the first resistor at the high resistance and the second resistor at the low resistance indicates a first logical state.

11. The ReRAM device of claim 10, wherein the first resistor at the low resistance and the second resistor at the high resistance indicates a second logical state, wherein the first logical state and the second logical state are opposite logical states.

12. A method for writing to a cell of semiconductor resistive random-access memory (ReRAM) device, comprising:
receiving a logical value to be written into the cell, the cell is a one-transistor two-resistor (1T2R) ReRAM cell having a first resistor and a second resistor;
determining based on the received logical value which of the first resistor and the second resistor is to be reset to a high resistive value;
resetting the resistor of the determined to be reset to a high resistive value; and
setting the other resistor of the cell determined to a low resistive value, wherein the combined opposite values of the first resistor and the second resistor are indicative of the logical value.

13. A method for reading from a cell of semiconductor resistive random-access memory (ReRAM) device, comprising:
determining a first resistive value of a first resistor of the cell, wherein the cell is a one-transistor two-resistor (1T2R) ReRAM cell;
determining a second resistive value of a second resistor of the cell;
assigning a first logical value on an output corresponding with the cell, when the first resistive value is high and the second resistive value is low; and
assigning a second logical value on the output corresponding with the cell, when the first resistive value is low and the second resistive value is high.

14. The method of claim 13, wherein the first logical value is an opposite logical value of the second logical value, and wherein the 1T2R ReRAM cell is written such that at no time the first resistor and the second resistor have each a low resistive value.

15. The method of claim 13, further comprising:
assigning a not a number (NaN) indication on the output corresponding with the 1T2R ReRAM cell when the first resistive value is high and the second resistive value is high.

16. The method of claim 13, further comprising:
determining, in parallel, the first resistive value and the second resistive value.

17. The method of claim 13, further comprising:
serially determining the first resistive value and the second resistive value.
